(19) United States
(12) Patent Application Publication
(10) Pub. No.: US 2022/0093810 A1
(43) Pub. Date: Mar. 24, 2022

(54) DEVICES COMPRISING MULTIPLE TWO-DIMENSIONAL TRANSITION METAL DICHALCOGENIDE MATERIALS

(71) Applicant: AGENCY FOR SCIENCE, TECHNOLOGY AND RESEARCH, Singapore (SG)

(72) Inventors: Steven LUKMAN, Singapore (SG); Jinghua TENG, Singapore (SG); Qing Yang Steve WU, Singapore (SG); Lu DING, Singapore (SG)

(21) Appl. No.: 17/413,927

(22) PCT Filed: Dec. 16, 2019
(86) PCT No.: PCT/SG2019/050615

§ 371 Date: Jun. 14, 2021

(30) Foreign Application Priority Data
Dec. 18, 2018 (SG) 10201811357T

(51) Int. Cl. H01L 31/032; H01L 31/0336; H01L 33/00

(52) U.S. Cl. CPC H01L 31/032; H01L 33/26; H01L 33/002; H01L 31/0336

(57) ABSTRACT

A device which detects and/or emits infrared radiation in the mid-infrared to far- infrared region is disclosed herein. The device comprises a first layer comprising a first transition metal dichalcogenide, and a second layer comprising a second transition metal dichalcogenide, wherein the second layer is deposited adjacent to the first layer to form a first interface which interlayer excitons are producible from for rendering the device operable to detect and/or emit infrared radiation in the mid-infrared to far-infrared region.

### CROSS-REFERENCE TO RELATED APPLICATION

This application claims the benefit of priority of Singapore Patent Application No. 10201811357T, filed 18 Dec. 2018, the content of it being hereby incorporated by reference in its entirety for all purposes.

### TECHNICAL FIELD

The present disclosure relates to devices comprising two or more different transition metal dichalcogenides stacked together.

### BACKGROUND

There has been interest in devices that detect and/or emit infrared (IR) radiation. Such devices may be a sensing device for air quality control, may be a leak detector, deployed in heat seeking missiles, optical communications, infrared imaging, or even spectroscopy.

Conventional infrared devices, however, may require cryogenic cooling to even operate, suffer from lattice mismatch with silicon readout (compromised lifetime of a device), require delicate and expensive material growth process, and/or their fabrication may involve toxic materials, high cost and complexity.

Two-dimensional (2D) photo-detectors based on graphene or other 2D materials have been developed to work around the limitations mentioned above. However, they tend to suffer from either low absorption coefficient, short carrier lifespan, or insufficient wavelength detection range.

There is thus a need to provide for a solution that addresses one or more of the limitations mentioned above. The solution should at least provide for a device that detects and/or emits infrared radiation in the mid-IR to far-IR range.

### SUMMARY

In a first aspect, there is provided for a device which detects and/or emits infrared radiation in the mid-infrared to far-infrared region, the device comprising: a first layer comprising a first transition metal dichalcogenide; and a second layer comprising a second transition metal dichalcogenide, wherein the second layer is deposited adjacent to the first layer to form a first interface which interlayer excitons are producible from for rendering the device operable to detect and/or emit infrared radiation in the mid-infrared to far-infrared region.

### BRIEF DESCRIPTION OF THE DRAWINGS

The drawings are not necessarily to scale, emphasis instead generally being placed upon illustrating the principles of the invention. In the following description, various embodiments of the present disclosure are described with reference to the following drawings, in which:

FIG. 1A illustrates the band gaps of two different layers of two-dimensional transition metal dichalcogenides stacked together. This represents an A-B heterostructure. The left is a layer of molybdenum disulfide and the right is a layer of hafnium disulfide. The bottom shaded region on the left denotes the valence band for molybdenum disulfide and the top shaded region on the right denotes the conduction band for hafnium disulfide. The shaded ellipse in the left layer depicts the nature of formation of an intralayer exciton. The shaded ellipse in contact with both left and right layers depicts the formation of an interlayer exciton. E_{interlayer} (i.e. E_{g,interlayer}) represents the energy gap (a difference in energy value) between the valence band of the left layer and the conduction band of the right layer. The present heterostructure can be represented, in terms of energy gap comparison, as E_{g,MoS}_{₂}>E_{g,HfS}_{₂}>E_{g,interlayer}.

FIG. 1B illustrates the band diagram of MoS₂ and HfS₂, and the radiative recombination of interlayer excitons between MoS₂ and HfS₂ that gives rise to photoluminescence (PL) (see band diagram on left). The plot on the right illustrates the mid-infrared (mid-IR) PL spectra tuned by applying a gate voltage, wherein the x-axis represents energy (eV) and the y-axis represents gate voltage (V_{g}) applied to the present device.

FIG. 2A shows the difference in band gap between three different two-dimensional transition metal dichalcogenides MoS₂, HfS₂ and WS₂.

FIG. 2B shows the heterostructure formed using three different two-dimensional transition metal dichalcogenides (top left band diagram), the spectra for photoabsorption (top right plot of relative (abbreviated “Rel.”) absorbance against energy), photoluminescence (bottom left plot of energy against gate voltage), and electroluminescence and the electroluminescence process (bottom right band diagram). The electroluminescence process is a form of photoluminescence rendered by an external electrical stimulus (e.g. injection of charge carriers, such as but not limited to, electrons). Referring to the top left band diagram, the transition metal dichalcogenides have been considered such that one has (i) a conduction band having a minimum energy value and (ii) a valence band having a maximum energy value, both of which are higher than those of the other two transition metal dichalcogenides. This transition metal dichalcogenide is denoted A. With such heterostructure, the excitons (i.e. electrons and/or their respective holes) that are producible, may move across to other transition metal dichalcogenides as shown, to occupy a lower energy level or state. An electron may remain in the transition metal dichalcogenide denoted B/C while its respective hole may remain in the transition metal dichalcogenide denoted A. Such positioning of the electron and its respective hole gives rise to an interlayer exciton. Due to strong oscillator strength of the transition, direct interlayer exciton may be directly formed instead of having to be formed from a charge hopping process at the interface. The strong optical transition may be manifested in the strong photon-absorption and/or emission from photo-excitation (as shown in FIG. 2B). On top of that, applying current (injecting charges) to the device, the electron and hole may meet and form an interface exciton at the interface and recombine to produce a photon by electroluminescence. Hence, this render the present device operable for light-emitting applications.

FIG. 2C shows a top-down optical microscope image of a stack built from three different transition metal dichalcogenides. The expression “1L” means one layer is used. The expression “3L” means three layers are used. The scale bar denotes 50 μm.

FIG. 3 shows a plot of absorbance against energy. This plot demonstrates that the present device is adapted to be more sensitive for detecting and/or emitting light in the mid-infrared to far-infrared range. Comparison is made between single layer transition metal dichalcogenides, multi-layered transition metal dichalcogenides, and a stacked trilayer of HfS₂/MoS₂/HfS₂ as a non-limiting example of the present device. The expression “1L” means one layer is used. The expression “5L” means five layers are used.

FIG. 4 shows the architecture of the present device, incorporating two stacked layers, wherein each stacked layer is either a photo-detector or a photo-emitter. The photo-detector and/or the photo-emitter are operable in the mid-IR to far-IR range. In FIG. 4, a stacked layer may be considered as two or more layers of transition metal dichalcogenides stacked. As shown in FIG. 4, there may be “1-n” of such layers, wherein “1-n” means 1 to n and n may range from 2 to 100. n may also be more than 100.

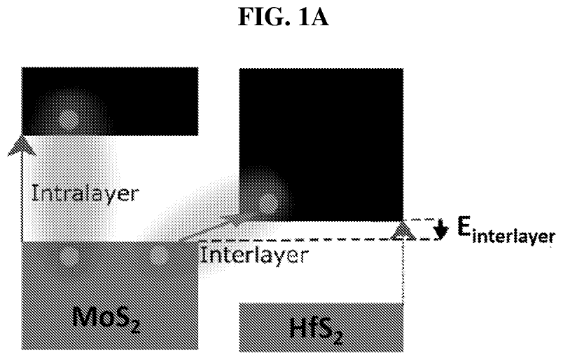

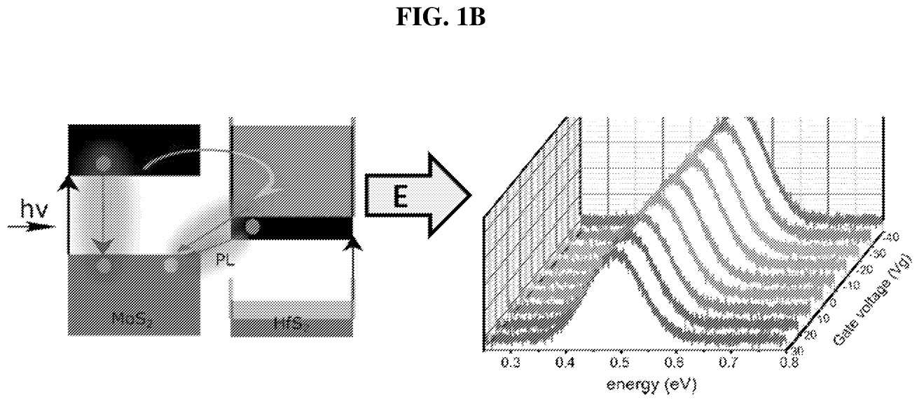

### DETAILED DESCRIPTION

The following detailed description refers to the accompanying drawings that show, by way of illustration, specific details and embodiments in which the invention may be practised.

Features that are described in the context of an embodiment may correspondingly be applicable to the same or similar features in the other embodiments. Features that are described in the context of an embodiment may correspondingly be applicable to the other embodiments, even if not explicitly described in these other embodiments. Furthermore, additions and/or combinations and/or alternatives as described for a feature in the context of an embodiment may correspondingly be applicable to the same or similar feature in the other embodiments.

The present disclosure relates to a device comprising two or more two-dimensional transition metal dichalcogenides. The two or more two-dimensional transition metal dichalcogenides may exist as two or more layers of transition metal dichalcogenides. The present device is operable as a photo-detector and/or photo-emitter, wherein the photo-detector and/or the photo-emitter are operable in the mid-infrared to far-infrared range.

The phrase “two-dimensional” used herein refers to a layer of crystalline material having a single layer of molecule. The thickness of a two-dimensional layer may range from 5 Å to 10 Å, e.g. 7 Å.

The term “transition metal” used herein refers to an element whose atom has a partially filled d sub-shell or one which can give rise to cations with an incomplete d sub-shell, in accordance with the definition of the International Union of Pure and Applied Chemistry (IUPAC). This may include, but not limited to, an element falling within groups 3 to 12 of the periodic table.

The term “dichalcogenide” used herein refers to a chemical compound having two chalcogen elements. The term “chalcogen” used herein refers to an element from group 16 of the periodic table. For example, a dichalcogenide may include within its meaning a disulfide, a diselenide, and a ditelluride.

The term “infrared” refers to light (or electromagnetic radiation) having photon energy in the range of 1.7 eV to 1.24 meV. The term “infrared” may be abbreviated herein as “IR” and include mid-IR and far-IR. The mid-IR and far-IR may share a common boundary or have a region that overlaps. For example, the mid-IR and far-IR may have a range of 83 meV to 413 meV and 1.2 meV to 83 meV, respectively.

Details regarding various embodiments of the present device are described below.

According to various embodiments of the first aspect of the present disclosure, there is provided for a device which detects and/or emits infrared radiation in the mid-infrared to far-infrared region. The device may comprise a first layer comprising a first transition metal dichalcogenide, and a second layer comprising a second transition metal dichalcogenide, wherein the second layer may be deposited adjacent to the first layer to form a first interface which interlayer excitons are producible from for rendering the device operable to detect and/or emit infrared radiation in the mid-infrared to far-infrared region. In various embodiments, the first transition metal dichalcogenide may be different from the second transition metal dichalcogenide.

The phrase “adjacent” used herein means that two layers arranged together, or one layer deposited over the other, are in contact. For example, the first layer deposited adjacent to the second layer, as mentioned above, means that the first layer and the second layer are in contact. When the first layer and the second layer are in contact, an interface defined by the contact between the first layer and the second layer is formed.

The term “interlayer”, as opposed to “intralayer”, used herein, indicates the presence of two layers arranged together to form an interface. Meanwhile, the term “intralayer” refers to one layer, such that excitons only move within that single layer.

The term “exciton” used herein refers to an electron bound to a hole, which are attracted to each other by an electrostatic Coulomb force, thereby resulting in zero net electric charge. The exciton may migrate from one layer to another layer through an interface defined by two layers of transition metal dichalcogenides that are in contact.

In the present device, two different layers of transition metal dichalcogenides may be stacked together to form a heterostructure having a heterojunction at the interface between the two different layers. Advantageously, interlayer excitons are producible therefrom even at room temperature. Cryogenic cooling is also not required for such excitons to be produced or for the present devices to be operable. The multiple layers of two-dimensional transition metal dichalcogenides may be transparent and/or flexible. The term “flexible” means the devices can be subjected to any form of contortion, e.g. bending, twisting, stretching, compression, without affecting its operability nor getting damage. Further advantageously, the present device may be operable as a photo-detector, a photo-emitter, or a combination thereof, in the range of visible light to far-IR due to the interface formed by two of such two-dimensional transition metal dichalcogenide layers. The stacked layers of two-dimensional transition metal dichalcogenide for the photo-detector and the photo-emitter can be incorporated separately to the same substrate, e.g. a silicon wafer, instead of requiring separate substrates.

The radiation band (e.g. visible, infrared) range in which the photo-detector and/or photo-emitter may operate in is tunable. The photo-detector and/or photo-emitter may be a dual- or multi-band device. This means the present device may operate for more than one radiation bands (visible and infrared radiations, mid-infrared and far-infrared radiations, etc.). The present device is versatile in that the tunability may be achieved through combination of different transition metal dichalcogenide layers and their thickness, chemical doping of each layer, application of an electrical field, etc.

To obtain the advantages mentioned above, the interface does not require chemical bonding of two layers of two-dimensional transition metal dichalcogenides. In this regard, the term “stack” and its grammatical variants used herein include within its meaning that no chemical bonding is formed between two layers that are arranged adjacent to each other. The two or more layers of two-dimensional transition metal dichalcogenides may be physically arranged to be in contact with one another through van der Waals force. In other words, the present device is workable in the absence of chemical bond between two layers of two-dimensional transition metal dichalcogenides (i.e. at the interface). Without chemical bonds formed between two layers of two-dimensional transition metal dichalcogenides, there is no lattice mismatch. There is also no lattice mismatch when the layers are stacked to a substrate. Moreover, surface defects are minimized. The surface defect refers to the absence of dangling bonds on the surface of a two-dimensional transition metal dichalcogenide material as opposed to the surface (e.g. of a three-dimensional material) that may have abruptly broken chemical bonds left dangling. Such dangling bonds tend to be reactive and traps charge carriers (e.g. electrons, excitons).

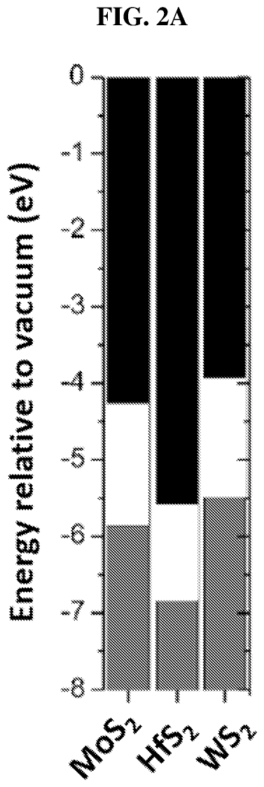

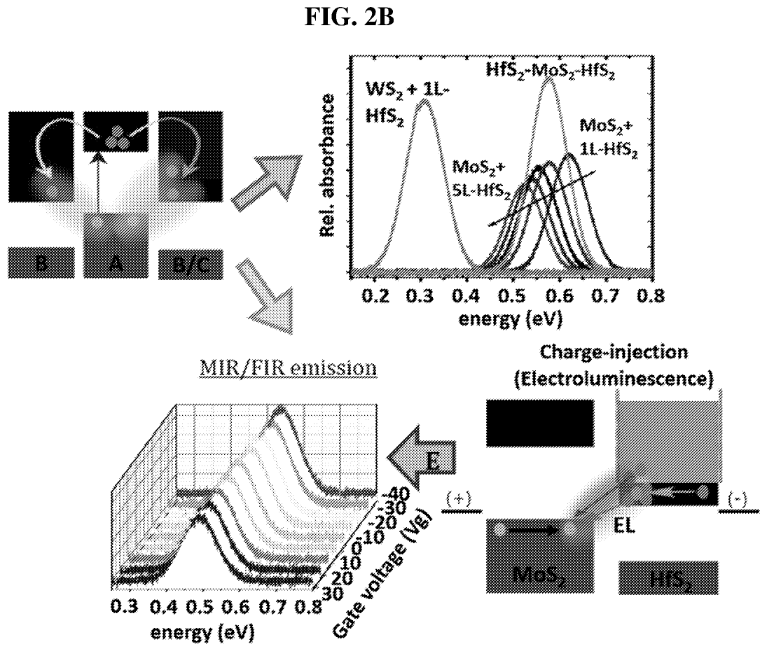

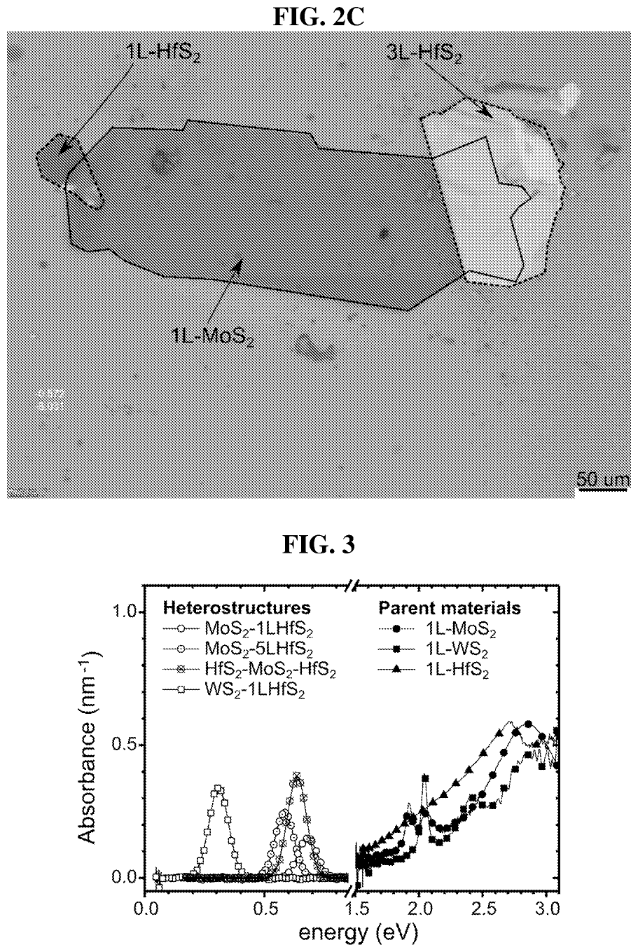

For a two-layered heterostructure, it may be abbreviated as “A-B”. For a three-layered heterostructure, it may be abbreviated as “A-B-A”, “B-A-B”, “A-B-C”, “B-A-C”, etc., wherein A, B and C all represent different transition metal dichalcogenides. The heterostructure of A-B-A and B-A-B may have enhanced semiconducting efficiency. Advantageously, the A-B-A heterostructure and B-A-B structure may act like a quantum well. Referring to FIG. 2A as an example, the electrons and respective holes of the interlayer excitons may accumulate at material B/C and A, respectively. Such structures favour the formation of interlayer excitons, rendering the device to have higher efficiency for operating as a photo-detector and/or photo-emitter. The heterostructure of A-B-C and B-A-C may have increased spectral operation range (e.g. from visible to far-IR).

In the present device, the first transition metal dichalcogenide may comprise a conduction band having a minimum energy value and the second transition metal dichalcogenide may comprise a valence band having a maximum energy value, and wherein the minimum energy value of the conduction band of the first transition metal dichalcogenide and the maximum energy value of the valence band of the second transition metal dichalcogenide may render a first difference in energy value for the interlayer excitons to be producible from the first interface. The difference in energy value for the interlayer excitons to be producible may be termed herein as an energy gap.

In the present device, alternatively, the first transition metal dichalcogenide may comprise a valence band having a maximum energy value and the second transition metal dichalcogenide may comprise a conduction band having a minimum energy value, and wherein the maximum energy value of the valence band of the first transition metal dichalcogenide and the minimum energy value of the conduction band of the second transition metal dichalcogenide may render a first difference in energy value for the interlayer excitons to be producible from the first interface. As already mentioned above, the difference in energy value for the interlayer excitons to be producible may be termed herein as an energy gap.

As mentioned above, two different layers of two-dimensional transition metal dichalcogenides stacked together advantageously provide for interlayer excitons to be producible therefrom. This applies for three or more stacked layers. When two different layers of two-dimensional transition metal dichalcogenides are stacked together, an exciton may migrate between the two layers. Each transition metal dichalcogenide may have its respective conduction band and valence band. The conduction band may have a minimum energy value and the valence band may have a maximum energy value. The exciton may migrate more easily between two different layers of transition metal dichalcogenide, for example, when the first layer of transition metal dichalcogenide has a valence band having a higher maximum value compared to that of the second layer of transition metal dichalcogenide and the second layer of transition metal dichalcogenide has a conduction band having a lower minimum energy value compared to that of the first layer of transition metal dichalcogenide. As a further example, the first layer of transition metal dichalcogenide has a conduction band having a lower minimum energy value compared to that of the second layer of transition metal dichalcogenide and the second layer of transition metal dichalcogenide has a valence band having a higher maximum value compared to that of the first layer of transition metal dichalcogenide. In both examples, the charge migration may take place in a manner to minimize the total energy of the electrons and holes thermodynamically by occupying lower energy states. An electron may move to a conduction band of another transition metal dichalcogenide having a lower energy value while the hole may reside in a valence band of a transition metal dichalcogenide having a lower energy value than the minimum energy value of the conduction band which the respective electron moved to. This generates the interlayer exciton, which may be tailored to have an energy in the mid- to far-IR range. A suitable photon, if present, may be absorbed to generate the interlayer exciton, rendering the present device operable as a photo-detector. The reverse process may be utilized for rendering the device operable as a photo-emitter. This advantage is also applicable to three or more stacked layers of different transition metal dichalcogenide. Depending on the layers of two-dimensional transition metal dichalcogenides stacked, efficiency of the detection for a particular wavelength (also depending on the energy gap for interlayer excitons to be producible) may be increased. The bandwidth of detection may be increased to more different ranges (i.e. two interlayer excitons from different energy gap may be formed when three different two-dimensional transition metal dichalcogenides get stacked together). The device may operate as a photo-emitter when the interlayer excitons, which can be photo- or electronically-generated, return to a ground state.

In embodiments where a third layer comprising a third transition metal dichalcogenide is involved, the third transition metal dichalcogenide may be (i) same as the first transition metal dichalcogenide or (ii) different from the first transition metal dichalcogenide and the second transition metal dichalcogenide. This allows for two different layers to form another semiconducting heterostructure having the interface described above. In other words, two interfaces may be formed, and each of these two interfaces may be different depending on the two-dimensional transition metal dichalcogenides used. Advantageously, the two interfaces may exhibit different characteristics allowing for the device to operate over a larger electromagnetic spectral range (e.g. from visible to far-IR).

The present device may further comprise a third layer deposited adjacent to the second layer to form a second interface which interlayer excitons are producible from for rendering the device operable to detect and/or emit infrared radiation in the mid-infrared to far-infrared region, wherein the third layer may comprise a third transition metal dichalcogenide.

In the present device, the third transition metal dichalcogenide may be identical to the first transition metal dichalcogenide.

In certain embodiments, the third transition metal dichalcogenide may comprise a valence band having a maximum energy value, and wherein the maximum energy value of the valence band of the third transition metal dichalcogenide and the minimum energy value of the conduction band of the second transition metal dichalcogenide may render a second difference in energy value for the interlayer excitons to be producible from the second interface.

In certain embodiments, the third transition metal dichalcogenide may comprise a conduction band having a minimum energy value, and wherein the minimum energy value of the conduction band of the third transition metal dichalcogenide and the maximum energy value of the valence band of the second transition metal dichalcogenide may render a second difference in energy value for the interlayer excitons to be producible from the second interface.

In various embodiments, the first transition metal dichalcogenide may comprise hafnium disulfide, molybdenum disulfide, molybdenum diselenide, titanium disulfide, tin diselenide, titanium diselenide, tungsten disulfide, tungsten diselenide, zirconium disulfide, or zirconium diselenide. Other transition metal dichalcogenides with suitable band alignment for the interlayer excitons to be producible may be used. Advantageously, such transition metal dichalcogenides are semiconducting, have a tunable band gap and high charge mobility. Such transition metal dichalcogenides also allow the present device to be operable as a photo-detector, photo-emitter, or a combination thereof. Said differently, stacking of such transition metal dichalcogenides allows for mid-IR to far-IR light absorption and/or emission.

In various embodiments, the second transition metal dichalcogenide may comprise hafnium disulfide, molybdenum disulfide, molybdenum diselenide, titanium disulfide, tin diselenide, titanium diselenide, tungsten disulfide, tungsten diselenide, zirconium disulfide, or zirconium diselenide. Other suitable transition metal dichalcogenides mentioned above for the first transition metal dichalcogenide may be used.

In various embodiments, the third transition metal dichalcogenide may comprise hafnium disulfide, molybdenum disulfide, molybdenum diselenide, titanium disulfide, tin diselenide, titanium diselenide, tungsten disulfide, tungsten diselenide, zirconium disulfide, or zirconium diselenide. Other suitable transition metal dichalcogenides mentioned above for the first transition metal dichalcogenide may be used.

In various embodiments, the device may comprise more than one of the first layer, more than one of the second layer, and/or more than one of the third layer. For example, there may be 1 to 20 of the first layers, 1 to 20 of the second layers, and/or 1 to 20 of the third layers.

In various embodiments, each of the first layer, the second layer and the third layer may comprise a thickness ranging from 5 Å to 10 Å, 5 Å to 7 Å, 7 Å to 10 Å, etc. The thickness may depend on the transition metal dichalcogenide used.

In various embodiments, the interlayer excitons are producible at a room temperature ranging from 293 K to 303 K.

In various embodiments, the device may further comprise a substrate which the first layer and the second layer may be deposited on, wherein the substrate comprises silicon. Silicon is a substrate that may be easily integrated for constructing the present device and it is an electronic substrate.

In various embodiments, the present device may further comprise a power source connectable thereto, wherein the power source may be operable to render a voltage applied to have the device detects and/or emits infrared radiation in the mid-infrared to far-infrared region. By changing the thickness of each layer or the number of layers of the transition metal dichalcogenides, the energy level of the interlayer excitons may be controlled. The power source may be connected to one of the layers of transition metal dichalcogenide and to the substrate.

The present device may be an infrared photo-detector, an infrared photo-emitter, or a combination thereof, operable in the mid-infrared to far-infrared region.

The word “substantially” does not exclude “completely” e.g. a composition which is “substantially free” from Y may be completely free from Y. Where necessary, the word “substantially” may be omitted from the definition of the invention.

In the context of various embodiments, the articles “a”, “an” and “the” as used with regard to a feature or element include a reference to one or more of the features or elements.

In the context of various embodiments, the term “about” or “approximately” as applied to a numeric value encompasses the exact value and a reasonable variance.

As used herein, the term “and/or” includes any and all combinations of one or more of the associated listed items.

Unless specified otherwise, the terms “comprising” and “comprise”, and grammatical variants thereof, are intended to represent “open” or “inclusive” language such that they include recited elements but also permit inclusion of additional, unrecited elements.

### EXAMPLES

The present disclosure relates to a device comprising two or more two-dimensional transition metal dichalcogenide (TDMC) semiconducting materials, and/or an alloy thereof. By putting together two of such different materials having a suitable band alignment and electron affinity, it is possible to generate interlayer exciton with energy that lies in the mid-IR and even far-1R range. Such a property may be utilized for IR photo emission and absorption from the exciton transition. The device may be simply fabricated and used as a photo-detector in the mid-IR range, in a photo-conductive mode. Electroluminescence may be observed by injecting a charge into the two-dimensional transition metal dichalcogenide materials. Such properties provide for further exploration of mid-IR and far-IR technologies, such IR sensing, solar energy harvesting, photo-emitter, IR laser, etc.

Various embodiments of the present device are described in further details, by way of non-limiting examples, as set forth below.

### Example 1A

### Preparation of the Present Device

Multi-layered samples were fabricated by means of a mechanical exfoliation transfer process. For this, MoS₂, WS₂ or HfS₂ flakes were first exfoliated from their respective bulk crystals onto separate polydimethylsiloxane substrates. The monolayer portion of these flakes were identified via optical microscopy, atomic force microscopy and Raman spectroscopy. Then, the first transition metal dichalcogenide material was transferred onto a target substrate, that is, a silicon wafer covered with a SiO₂ layer and pre-defined metal markers. Subsequently, the second transition metal dichalcogenide material was transferred on top of the first transition metal dichalcogenide material. The third transition metal dichalcogenide was transferred in a similar manner thereafter for forming samples with three different transition metal dichalcogenides. After completing the transfer, the samples were annealed under Ar gas at 150° C. for few hours. Other transition metal dichalcogenides usable include molybdenum diselenide, titanium disulfide, tin diselenide, titanium diselenide, tungsten diselenide, zirconium disulfide, and zirconium diselenide.

### Example 1B

### Characterization of Energy Values of a Conduction band and Valence Band

Differential conductance (dI/dV) spectra may be used to determine the maximum energy value of a valence band and the minimum energy value of a conduction band. The wide band gap and several prominent peaks were observable in the measurement. The band edges (maximum energy value of valence band and minimum energy value of conduction band) may be determined by the logarithm of the differential conductance (dI/dV) of the spectra. The maximum value of the valence band and the minimum value of the conduction band may be determined from the onset of a gradual rapid increase in the conductance of a transition metal dichalcogenide while a negative and positive gate voltage is applied, respectively. For determining a band gap between a conduction band and a valence band of the same transition metal dichalcogenide, this can be observed from a conductance that is very small (close to or equal zero) as there is no energy level to accommodate any charge carriers in the band gap.

### Example 2A

### Summary of Present Device

In various instances, the present device has a type II semiconductor structure that is formed by stacking two or more different transition metal dichalcogenides for use in applications that involve the mid-IR, and/or even far-IR region. For example, the present device can have a type II semiconductor structure that is formed by stacking two or more different transition metal dichalcogenides so as to have the device operable as a photo-detector and/or light-emitting device in the mid-1R and/or far-IR range.

In other instances, the present device can have a type II semiconductor structure that is formed by stacking three or more different transition metal dichalcogenides so as to have the device operable as a photo-detecting and/or light-emitting device in the mid-IR and/or further down to far-IR range. Such a device can include three layers of the transition metal dichalcogenides, wherein one of the layers is a lower electron affinity material sandwiched between the other two layers, wherein the other two layers are of a higher affinity material, to form the three-layered structures.

The present device can be constructed to be a type II semiconductor structure by stacking two or more different transition metal dichalcogenides on a single substrate, such that the type II semiconductor structure allows the device to be operable as a photo-detector and a light emitting device in the mid-IR and even far-IR range, even when the two or more different transition metal dichalcogenides are stacked on the same substrate. The substrate may be a wafer. The wafer can be a silicon wafer or a doped silicon wafer. The doped silicon wafer can be a p-doped silicon wafer. In other words, the present device comprised of two or more different transition metal dichalcogenides stacked together may act collectively as photo-detector and photo-emitter. When a strong light source or an electrical source is provided to generate the interlayer excitons, the device can be operable as a photo-emitter. Interlayer excitons may be formed in the presence of an external stimuli, such as but not limited to, optical (photon of suitable energy) or electrical stimulus (injection of charge carrier to the interface).

The present device can be a two-dimensional semiconductor structure that is formed by stacking two or more different two-dimensional transition metal dichalcogenides that allows the device to be operable as a dual- or multi-band photo-detector in the range of visible wavelength to far-IR. This would include near-IR and mid-IR range.

Holistically, the present device involves a mid-IR technology that is workable even for room temperature operation without the need for cryogenic cooling, as the operation of the device can be phonon-assisted.

The semiconductor structure of the present device can be grown, transferred, or combined with any materials without lattice mismatch constraint or generation of interfacial defects. The semiconductor structure of the present device can be made from two-dimensional transition metal dichalcogenides materials that can produce an optical response tunable by electrical bias. As illustrated in FIG. 2B, the electrical bias changes the relative band alignment of the stacked materials, thus the energy required for the formation of interlayer excitons may also be affected. As a result, the energy range where interlayer excitons absorb or emit also changes. This is useful in tuning the optical range for rendering the present device photo-active (absorb and/or emit light). The present device may be optically active (i.e. photo-active) in the mid-IR to far-IR region.

The present device can be operated as a room temperature photo-detector and/or photo-emitter. This is due to the interlayer excitons generated between (i.e. at the interface) the two-dimensional transition metal dichalcogenides. The absorption and emission of the photons can be mediated by phonons, hence the device can be used favourably at room temperature. In contrast thereto, conventional mid-IR device tends to require cooling.

The present device also possesses tunability of the wavelength detectable and/or emittable. This tunability arises from the combination of materials (type and/or thickness) used (e.g. using two or more different two-dimensional transition metal dichalcogenides). The thickness of the transition metal dichalcogenides may influence the band gap alignment, thereby affecting the energy required for formation of the interlayer excitons. As a result, the energy range where interlayer excitons absorb and/or emit also changes. This may be useful in tuning the optical range for the device is rendered photo-active. The thickness may be tuned by using more than 1 layer, e.g. up to 20 layers. The thickness of a layer of transition metal dichalcogenide may also be tuned by using more than 1 layer (e.g. up to 20 layers) of that one transition metal dichalcogenide.

While a broad tuning of wavelength can be achieved through the materials used for forming the stack of two-dimensional transition metal dichalcogenides, fine tuning can be done by doping the two-dimensional transition metal dichalcogenides with a chemical, applying an electric field, changing the photo-excitation and charge injection density within the same material, etc. The ability for the device to be tuned for operating over a broad range of wavelength or a more specific range of wavelength, due to the two-dimensional transition metal dichalcogenides stacked, renders the present device versatile.

The two-dimensional transition metal dichalcogenides, and hence the device, can be easily integrated or combined with other materials (including the substrate), as there is no need to form chemical bonds between the stacked two-dimensional transition metal dichalcogenides. In other words, the interface between two different layers of two-dimensional transition metal dichalcogenides is absent of chemical bonds.

Advantageously, there is no need for lattice matching to stack the two or more layers of two-dimensional transition metal dichalcogenides, and there is also no adverse effects (e.g. surface defects) that may impair the devices' performance (charge extraction or injection for photovoltaic detector and light emitting device) from the stacking of two-dimensional transition metal dichalcogenides.

The device can be an ultrathin device (in the nanometer range) due to the two-dimensional transition metal dichalcogenides used.

As already mentioned above, the present device is workable for dual-band operation, wherein the present device as a photo-detector can respond to both visible-near IR light and mid-IR light. The present device can be fabricated as a large area, transparent and efficient optoelectronics devices from such a type II semiconducting structure built using two or more different layers of two-dimensional transition metal dichalcogenides.

### Example 2B

### Present Device Based on HfS₂/MoS₂/HfS₂

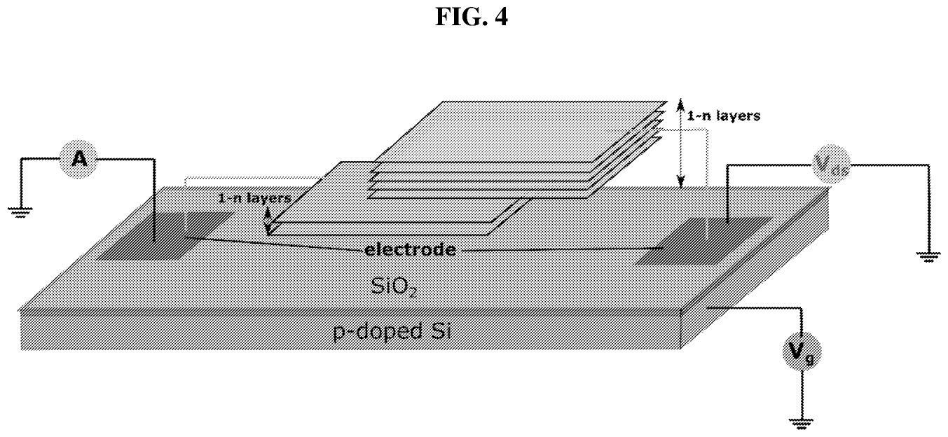

A non-limiting example of the present device is demonstrated using three layers of two-dimensional transition metal dichalcogenides. The three layers stacked in contact can be represented as HfS₂/MoS₂/HfS₂. Such a device is illustrated, by way of a non-limiting schematic example, in FIG. 4.

The device is tunable and operable as a mid-IR to far-IR photo-detector that works based on the multi-layered two-dimensional transition metal dichalcogenides. The device is capable of a large optical amplitude absorption of interlayer exciton based on the two-dimensional transition metal dichalcogenides used, which is comparable or even superior to intralayer exciton, and is different in terms of a few order of magnitudes. For example, the value of absorbance of intralayer exciton and present interlayer exciton may differ to be at least about 10⁻¹ nm⁻¹.

The device, based on such two-dimensional transition metal dichalcogenides, can also work as a light emitter due to strong oscillator transition. The monolithic integration of both light emitter and photo-detector side by side on the same substrate is possible as shown in FIG. 4, which is conventionally difficult when other materials are used. Advantageously, the present device and the two-dimensional transition metal dichalcogenides are operable at room temperature, and no cooling is required to suppress thermal-generated charge carriers, which is a common issue plaguing conventional technology.

The present device is operable as a dual- or multi-band photo-detector in the visible and mid-IR light range. The photo-active detection and/or emission range is tunable with externally applied gate voltage (Vg). Advantageously, the present device and the stacked layers of two-dimensional transition metal dichalcogenides have a higher efficiency by employing “quantum well” type of heterostructure constructed from the non-limiting examples of HfS₂/MoS₂/HfS₂, HfS₂/WS₂JHfS₂, SnSe₂/WS₂/SnSe₂. The quantum well may be derived from a thin layer of material that can confine an electron or a hole in the dimension perpendicular to the surface, where the movement is not restricted.

### Example 3

### Commercial and Potential Applications

The present technology of the present device can be used for mid-IR thermal imaging, thermography for non-destructive testing, gas leakage and explosive detectors, environmental sensing of air quality and air pollution, chemical and biomolecular sensing, material processing, and spectroscopy.

While the invention has been particularly shown and described with reference to specific embodiments, it should be understood by those skilled in the art that various changes in form and detail may be made therein without departing from the spirit and scope of the invention as defined by the appended claims. The scope of the invention is thus indicated by the appended claims and all changes which come within the meaning and range of equivalency of the claims are therefore intended to be embraced.

1. A device which detects and/or emits infrared radiation in the mid-infrared to far-infrared region, the device comprising:
a first layer comprising a first transition metal dichalcogenide; and
a second layer comprising a second transition metal dichalcogenide, wherein the second layer is deposited adjacent to the first layer to form a first interface which interlayer excitons are producible from for rendering the device operable to detect and/or emit infrared radiation in the mid-infrared to far-infrared region.

2. The device of claim 1,
wherein the first transition metal dichalcogenide comprises a conduction band having a minimum energy value and the second transition metal dichalcogenide comprises a valence band having a maximum energy value, and wherein the minimum energy value of the conduction band of the first transition metal dichalcogenide and the maximum energy value of the valence band of the second transition metal dichalcogenide render a first difference in energy value for the interlayer excitons to be producible from the first interface; or wherein the first transition metal dichalcogenide comprises a valence band having a
maximum energy value and the second transition metal dichalcogenide comprises a conduction band having a minimum energy value, and wherein the maximum energy value of the valence band of the first transition metal dichalcogenide and the minimum energy value of the conduction band of the second transition metal dichalcogenide render a first difference in energy value for the interlayer excitons to be producible from the first interface.

3. The device of claim 1, further comprising a third layer deposited adjacent to the second layer to form a second interface which interlayer excitons are producible from for rendering the device operable to detect and/or emit infrared radiation in the mid-infrared to far-infrared region, wherein the third layer comprises a third transition metal dichalcogenide.

4. The device of claim 3, wherein the third transition metal dichalcogenide is identical to the first transition metal dichalcogenide.

5. The device of claim 3,
wherein the third transition metal dichalcogenide comprises a valence band having a maximum energy value, and
wherein the maximum energy value of the valence band of the third transition metal dichalcogenide and the minimum energy value of the conduction band of the second transition metal dichalcogenide render a second difference in energy value for the interlayer excitons to be producible from the second interface.

6. The device of claim 3,
wherein the third transition metal dichalcogenide comprises a conduction band having a minimum energy value, and
wherein the minimum energy value of the conduction band of the third transition metal dichalcogenide and the maximum energy value of the valence band of the second transition metal dichalcogenide render a second difference in energy value for the interlayer excitons to be producible from the second interface.

7. The device of any one of claim 1, wherein the first transition metal dichalcogenide comprises hafnium disulfide, molybdenum disulfide, molybdenum diselenide, titanium disulfide, tin diselenide, titanium diselenide, tungsten disulfide, tungsten diselenide, zirconium disulfide, or zirconium diselenide.

8. The device of claim 1, wherein the second transition metal dichalcogenide comprises hafnium disulfide, molybdenum disulfide, molybdenum diselenide, titanium disulfide, tin diselenide, titanium diselenide, tungsten disulfide, tungsten diselenide, zirconium disulfide, or zirconium diselenide.

9. The device of claim 3, wherein the third transition metal dichalcogenide comprises hafnium disulfide, molybdenum disulfide, molybdenum diselenide, titanium disulfide, tin diselenide, titanium diselenide, tungsten disulfide, tungsten diselenide, zirconium disulfide., or zirconium diselenide.

10. The device of claim 3, wherein the device comprises more than one of the first layer, more than one of the second layer, and/or more than one of the third layer.

11. The device of claim 3, wherein each of the first layer, the second layer and the third layer comprises a thickness ranging from 5 Å to 10 Å.

12. The device of claim 1, wherein the interlayer excitons are producible at a room temperature ranging from 293 K to 303 K.

13. The device of claim 1, further comprising a substrate which the first layer and the second layer are deposited on, wherein the substrate comprises silicon.

14. The device of claim 1, further comprising a power source connectable thereto, wherein the power source is operable to render a voltage applied to have the device detects and/or emits infrared radiation in the mid-infrared to far-infrared region.

15. The device of claim 1, wherein the device is an infrared photo-detector, an infrared photo-emitter, or a combination thereof, operable in the mid-infrared to far-infrared region.
